(19) United States
(12) Patent Application Publication
(10) Pub. No.: US 2007/0053168 A1
(43) Pub. Date: Mar. 8, 2007

(54) ADVANCED HEAT SINKS AND THERMAL SPREADERS

(75) Inventors: Haluk Sayir, Bay Village, OH (US); Arik Mehmet, Niskayuna, NY (US); Evan B. Cooper, Orange Village, OH (US); Tunc Icoz, Schenectady, NY (US); Marc Schaepkens, Medina, OH (US); Xiang Liu, Medina, OH (US)

Correspondence Address: GEAM - QUARTZ;IP LEGAL, ONE PLASTICS AVENUE, PITTSFIELD, MA, 01201-3697, US

(73) Assignee: General Electric Company, Schenectady, NY (US)

(21) Appl. No.: 11/555,681

(22) Filed: Nov. 1, 2006

Related U.S. Application Data
(63) Continuation-in-part of application No. 10/761,567, filed on Jan. 21, 2004.
(60) Provisional application No. 60/743,998, filed on Mar. 30, 2006.

(51) Int. Cl. H05K 7/20

(52) U.S. Cl. 361/718; 361/709; 361/710

(57) ABSTRACT

A heat sink assembly for an electronic device or a heat generating device(s) is constructed from an ultra-thin graphite layer. The ultra-thin graphite layer exhibits thermal conductivity which is anisotropic in nature and is greater than 500 W/m° C. in at least one plane and comprises at least a graphene layer. The ultra-thin graphite layer is structurally supported by a layer comprising at least one of a metal, a polymeric resin, a ceramic, and a mixture thereof, which is disposed on at least one surface of the graphite layer.

### CROSS-REFERENCE TO RELATED APPLICATIONS

This application claims the benefits of U.S. Patent Appl. No. 60/743998 filed Mar. 30, 2006, which patent application is fully incorporated herein by reference. This application is also a continuation-in-part (CIP) of U.S. patent application Ser. No. 10/761,567, with a filing date of Jan. 21, 2004.

### FIELD OF THE INVENTION

The present invention relates to a thermal management assembly including but not limited to a heat spreader, which can be used for transferring heat away from a heat source, e.g., to a heat sink; an assembly having the heat spreader in contact with the heat source, e.g., between the heat source and the heat sink; a heat sink for dissipating the heat. The invention also relates to methods of manufacturing a thermal management assembly.

### BACKGROUND OF THE INVENTION

Advances in microelectronics technology have resulted in electronic devices which process signals and data at unprecedented high speeds. Electronic and/or integrated circuit (“IC”) devices, e.g., microprocessors, memory devices, etc, become smaller while heat dissipation requirements get larger. Thermal energy generated within electronic devices such as personal computers can be compared to that of a stovetop burner, with today's generation of Pentium and Power PC chips dissipating more than 100 watts of power. In simple terms, one could fry an egg on top of any of these chips.

The heat must be efficiently removed, to prevent the system from becoming unstable or being damaged. Heat spreaders and/or heat sinks are frequently used to dissipate heat from the surface of electronic components to a cooler environment, usually ambient air. The heat transfer rate from heat source surfaces directly to the surrounding air is typically poor.

A heat sink is a thermal dissipation device comprised of a mass of material that is thermally coupled to a heat source to conduct thermal energy away from the heat source. Heat sinks are typically designed to transport the heat from the heat spreader on the IC to ambient air. The heat sink may be in the form of fins or an integrated heat spreader. The heat sink conducts the thermal energy away from a high-temperature region (i.e., the processor) to a low-temperature region (i.e., the heat sink). The thermal energy is then dissipated by convection and radiation from a surface of the heat sink into the atmosphere surrounding the heat sink. Heat sinks are typically designed to increase the heat transfer efficiency primarily by increasing the surface area that is in direct contact with the air. This allows more heat to be dissipated and thereby lowers the device operating temperature.

Heat sinks used for cooling electronic components typically include a thermally conductive base plate that interfaces directly with the device to be cooled and a set of plate or pin fins extending from the base plate. The fins increase the surface area that is in direct contact with the air, and thereby increase the heat transfer efficiency between the heat source and ambient air.

In conventional heat sinks of the prior art, the fins are either integral with the base of the heat sink or assembled to the base using various conventional fastening techniques. In heat sinks where the base and the fins are assembled together, the base is typically either copper or aluminum, and the fins are either copper or aluminum. Copper has superior thermal conductivity as compared to aluminum (390 vs. 101 W/m·K), but is more expensive. Copper is also denser, adding weight to the heat sink and making the heat sink, and the electronic device more vulnerable to damage from shock and/or vibration. Therefore, heat sinks that have copper are heavy and costly while aluminum fins do not provide enough thermal performance. U.S. Pat. No. 6,862,183 discloses a heat sink having composite fins, i.e., each fin including a first portion made from copper that is thermally coupled to a base to conduct thermal energy away from the base, and a second portion made from aluminum.

To overcome the weight problems of conventional heat sinks employing copper and/or aluminum, heat sinks employing graphite have been proposed. U.S. Pat. No. 6,538,892 discloses a radial finned heat sink assembly having planar fins with graphite layers aligned with plane of fin, such that thermal conductivity in direction parallel to plane is greater than that in perpendicular direction. Each fin comprises a graphite “sheet” that has been compressed or compacted with the density and thickness of each graphite sheet varied by controlling the degree of compression, for a thickness of about 0.075 mm to 3.75 mm. U.S. Pat. No. 6,749,010 discloses a heat sink system having a metal base and a plurality of fins attached to the base, the fins constructed of a resin impregnated laminate of “sheets” of compressed particles of exfoliated graphite, with each graphite sheet having thickness of about 0.075 mm to 3.75 mm.

Using graphite is one way to overcome the weight problems of the aluminum/copper heat sinks of the prior art. However, the prior art graphite heat spreaders are directed at graphite “sheets” comprising plurality of graphite layers or cleavings at the micrometer level. There exists a need for advanced thermal management systems with ultra-thin heat sinks for a maximized ratio of thermal conductivity to weight.

### BRIEF SUMMARY OF THE INVENTION

The invention provides a thermal management assembly for dissipating thermal energy from an electronic device or a similar system requires heat removal. The assembly comprises a base adapted to be thermally coupled to the electronic device; and at least a heat sink thermally coupled to the base. The heat sink comprises at least a graphite layer exhibiting a thermal conductivity which is anisotropic in nature and is greater than 500 W/m° C. in at least one plane, the graphite layer has a first surface, a second surface, and a thickness comprising at least a graphene layer. The graphite layer is structurally supported by a later comprising at least one of a metal, a polymeric resin, a ceramic, and a mixture thereof disposed on at least one surface of the graphite layer.

The invention further relates to a method for constructing a fin for use in a heat sink, by cleaving at least a graphite layer having a thickness of less than 0.1 from a sheet of graphite exhibiting a thermal conductivity which is anisotropic in nature and is greater than 500 W/m° C. in at least one plane to obtain a graphite layer comprising at least a graphene layer.

### BRIEF DESCRIPTION OF THE DRAWING

FIG. 1 is a perspective view illustrating a graphite cleaving comprising a plurality of graphene layers having atomic thickness.

FIGS. 2A, 2B and 2C are sectional view across a fin thickness, showing various embodiments of the heat sink of the invention.

FIGS. 3A and 3B are a partial sectional view showing one embodiment of the invention in the course of manufacturing the heat sink.

FIG. 4 is a partial sectional view showing one embodiment of a heat sink with a bent fin configuration, with a portion oriented horizontally into the base plate and the remaining portion oriented vertically.

FIG. 5 is a perspective view showing one embodiment of a heat sink having a plurality of rectangular fins attached to a base.

FIG. 6 is a perspective view showing one embodiment employing the ultra-thin graphite heat sink of the invention, in the form of a radial fin.

FIG. 7 is a perspective view showing one embodiment employing the ultra-thin graphite heat sink of the invention, in the form of a folded fin.

FIG. 8 is a perspective view showing a second embodiment of the ultra-thin graphite heat sink of the invention, employing a folded fin.

FIG. 9 is a perspective view of yet another embodiment employing a folded fin.

FIG. 10 is a perspective view of another embodiment, for a partial radial finned heat sink.

FIG. 11 is a perspective view showing another embodiment of the embodiment, with a pin-fin heat sink.

FIG. 12 is a perspective view showing an ultra-thin/ultra-light heat sink with a honeycomb-like, cellular structure.

FIG. 13 is a perspective view showing an ultra-thin heat sink in the form of an expanded bundle or a splayed pattern.

FIG. 14 is a side view showing an ultra-thin heat sink having a plurality of slits defining different stages of airflow channels.

FIG. 15 is a graph illustrating the conductive thermal resistance as a function of thermal conductivity in a heat sink assembly comprising fins of various sizes.

FIG. 16 is another graph, which illustrates the conductive thermal resistance as a function of thermal conductivity in heat sink assemblies comprising fins of different materials.

### DETAILED DESCRIPTION OF THE INVENTION

As used herein, approximating language may be applied to modify any quantitative representation that may vary without resulting in a change in the basic function to which it is related. Accordingly, a value modified by a term or terms, such as “about” and “substantially,” may not to be limited to the precise value specified, in some cases.

The term “heat sink” may be used interchangeably with “heat dissipator” and that the term may be in the singular or plural form, indicating one or multiple items may be present, referring to an element which not only collects the heat, but also performs the dissipating function.

As used herein, the term “base plate,” “base plate” or “mounting frame” may be used interchangeably, referring to the thermally conductive structure or element that interfaces directly with a heat spreader, the device to be cooled or for the heat to be removed from. As used herein the term “heat spreader” refers to a device typically in the form of a sheath, that is in contact with the source of heat and the heat sink. A heat spreader sometimes also functions as an isolator to protect fragile IC components during shock and vibration,

Also as used herein, the term “thermal pyrolytic graphite” (“TPG”) may be used interchangeably with “highly oriented pyrolytic graphite” (“HOPG”), or compression annealed pyrolytic graphite (“CAPG”), referring to graphite materials consisting of crystallites of considerable size, the crystallites being highly aligned or oriented with respect to each other and having well ordered carbon layers or a high degree of preferred crystallite orientation, with an in-plane (a-b direction) thermal conductivity greater than 1000 W/m-K. In one embodiment, the TPG has an in-plane thermal conductivity greater than 1,500 W/m-K

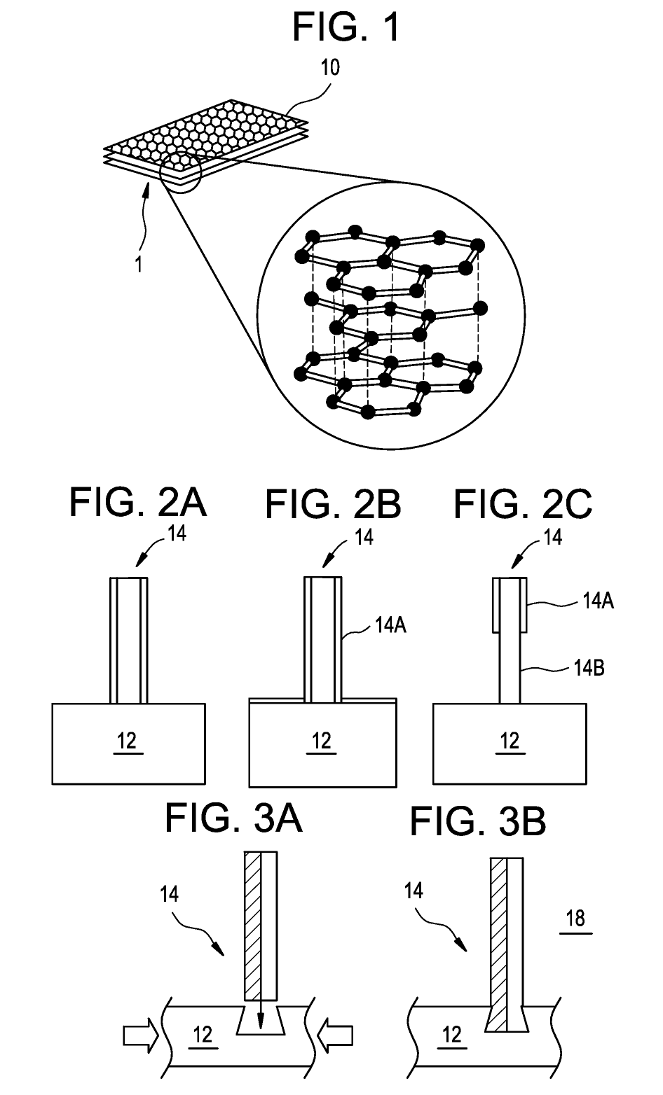

As used herein, the term “graphene” or “graphene film” denotes the atom-thick carbon sheets or layers (as illustrate in FIG. 1) that stacks up to form “cleavable” layers (or mica-like cleavings) in graphite.

The invention relates to an advanced thermal management system, i.e., an ultra-thin heat sink, comprising at least a single layer or a single cleaving of graphite for a maximized ratio of thermal conductivity to weight.

Graphites possess anisotropic structures and thus exhibit or possess many properties that are highly directional e.g. thermal and electrical conductivity and fluid diffusion. Graphites are made up of layer planes of hexagonal arrays or networks of carbon atoms. As illustrated in FIG. 1, these layer planes 10 of hexagonally arranged carbon atoms are substantially flat and are oriented or ordered so as to be substantially parallel and equidistant to one another. The substantially flat, parallel equidistant sheets or layers 10 of carbon atoms, usually referred to as graphene layers or basal planes, are linked or bonded together and groups thereof are arranged in crystallites. The superposed layers or laminate of carbon atoms in graphite are joined together by weak van der Waals forces. In considering the graphite structure, two axes or directions are usually noted, to wit, the “c” axis or direction and the “a” axes or directions. The “c” axis or direction may be considered as the direction perpendicular to the carbon layers. The “a” axes or directions may be considered as the directions parallel to the carbon layers or the directions perpendicular to the “c” direction.

As graphite is made up of a plurality layers or planes, and because of its layered structure, graphite cleaves almost like mica along the basal planes. Using a simplistic process such as taking a piece of tape and pressing it onto the flat graphite surface and then pull it off, and the tape takes with is a thin cleaving 1 of graphite. As shown in FIG. 1, each cleaving 1 comprises a plurality of graphene layers 10 of atomic layers (unit cell layers) of carbon. It has been reported that for a sheet of graphite block of a 2 mm thick, one can get 20-40 cleavings of 25-50 μm. The higher the quality of graphite, the more cleavings one can get per mm of graphite sheet and the thinner the cleaving of graphite. A heat sink design can be a complex task requiring extensive math—finite element analysis, fluid dynamics, etc. In designing heat sinks, various factors are taken into consideration, including thermal resistance, area of the heat sink, the shape of the heat sink, i.e., whether finned or pin design and the height of pins or fins, whether a fan is used and its air flow rate, heat sink material, and maximum temperature to be allowed at die.

Thermal resistance is the critical parameter of heat sink design. Thermal resistance is directly proportional to thickness of the material and inversely proportional to thermal conductivity of the material and surface area of heat flow. The invention relates to an advanced thermal management system with optimized thermal resistance, i.e., an ultra-thin heat sink comprising a conductive material such a graphite, with thermal conductivity as high as 1000 W/m-K or more, with a thickness as low as one atomic layer of carbon.

Process for Manufacturing Advanced Thermal Spreader of Ultra-thin Thickness In one embodiment, a pyrolytic graphite (“PG”) sheet is used as the feedstock source for the ultra-thin cleavings of graphite for use in the advanced thermal spreader of the invention. PG is generally is made by passing a carbonaceous gas at low pressure over a substrate held at a high temperature, wherein pyrolysis occurs and the graphite is vapor-deposited on the exposed mandrel surface. The pyrolytic graphite sheet is separated from the base substrate, and further subjected to a thermal annealing process. In the annealing step, the PG is heated at a temperature of above 2900° C. for a sufficient period of time, depending on the thickness and bulk of the product being annealed, forming thermal pyrolytic graphite (“TPG”). In one embodiment, this sufficient amount of time is a minute or less. In a second embodiment, 45 seconds. In a third embodiment, 30 seconds. In a fourth embodiment, 10 seconds. In the annealing process, crystallographic changes take place resulting in an improvement in layer plane orientation, a decrease in thickness normal to the layer planes (decrease in the c direction), and an increase in length and width dimensions (increase in the a direction). The improved orientation along with an increase in crystallization size results in an excellent thermal conductivity of least 1000 watts/m-K in the finished material in certain directions. In one embodiment, the PG layers are hot pressed while undergoing annealing, for TPG sheets of excellent thermal conductivity and parallelism of the graphite layers or cleavings. The hot pressing may be done using processes and apparatuses known in the art, e.g., using dies, rollers, and the like.

As used herein, the term “graphite layer” refers to a single cleaving of PG comprising least one graphene layer of nanometer thickness. Also as used herein, the term “cleave” or “cleaving” refers to the process of peeling, removing, or extracting from, or separating a sheet of graphite to obtain at least an ultra-thin layer of graphite, comprising at least one single graphene layer of nanometer thickness. The “sheet” of graphite comprises at least two cleavings or layers of graphite, each in turns comprises a plurality of graphene layers.

Although the generic term “graphite” may be used herein, the ultra-thin heat sink of the invention depending on the application employs either pyrolytic graphite (PG) with a typical in-plane (a-b direction) thermal conductivity of less than 500 W/m-K, or thermal pyrolytic graphite (TPG) with an in-plane (a-b direction) thermal conductivity greater than 600 W/m-K. In one embodiment, the starting feedstock is a graphite sheet commercially available from sources including Panasonic, General Electric Company, etc., with thickness of 0.1±0.05 mm.

Preparing an Ultra-thin Graphite Layer Comprising Graphene Layers: In one embodiment, the graphite sheet is first treated with an intercalating agent known in the art to facilitates the exfoliation or separation of the layers to obtain cleavings of graphitized pyrolytic graphite in the c axis. After intercalation, i.e., being treated with the intercalating agent, the treated pyrolytic graphite may be washed or purged free of excess intercalating agent. Examples of intercalating agent include organic and inorganic acids such as nitric acid, sulfuric acid, perhalo acid and mixtures thereof, 7,7,8-8-tetracyanoquinomethane (TCNQ), tegracyanoethylene (TCNE), 1,2,4,5-tetracyanobenzene (TCBN), and the like; bromine and ferric chloride; nitric acid and chlorate of potash.

In yet another embodiment, a chemical source such as particles, fluids, gases, or liquids is first introduced to increase stress in the region between the graphene layers, for weakened interlayer interactions, inducing the graphene layers to exfoliate from the graphite surface. In one embodiment, the particles from the chemical source are introduced into the cleaving layer in a selected dosage to facilitate cleaving in a controlled manner. In one embodiment, an agent such as acetone, benzene, naphthalene is used to cause the graphene layers to exfoliate from the graphite surface by weakening their interlayer interactions.

In one embodiment, the separate graphene layers are obtained using ultrasonic, wherein a selectivity property of ultrasonic is employed for concentrating energies at interconnected interfaces between the graphene layers. As the interlayer interfaces between the graphene becomes weakened through the use of a chemical source such as acetone, benzene, etc., the energies of ultrasonic are absorbed to part and break away the graphene layers, thereby effectively and rapidly separating the graphene layers. The ultrasonic condition, i.e., frequency, power, time, etc., varies depending on the chemical source used to weaken the interlayer interactions of the graphene.

In yet another embodiment, the graphene layers are cleaved using micromechanical manipulations as described by Zhang et al. in APPLIED PHYSICS LETTERS 86, 073104 2005, May 6, 2005, to obtain graphite crystallites having thickness d ranging from 10 to 100 nm. The article is herein incorporated by reference. In this method a graphite sheet or block is transferred to a micro-machined silicon cantilever and glued down by using an adhesive. Thin microscopic cleaving can be obtained/controlled by tuning the normal force between the cantilever and the substrate.

In one embodiment, a separate cleaving comprising at least a graphene layer is obtained by pressing a sheet of PG against a layer of photoresist spread over glass substrate, for the top cleaving of PG comprising at least one graphene layer to attached to the photoresist layer. The photoresist layer can be dissolved away in solvents such as acetone, leaving behind the single cleaving layer of PG with at least one graphene layer of nanometer thickness.

In yet another embodiment, copper, aluminum, or tinned copper foil tapes backed with a highly conductive pressure-sensitive adhesive are pressed against a pyrolytic graphite substrate and peeled of, for a cleaving of pyrolytic graphite comprising at least one graphene film or layer. In one embodiment, the metal foil has a thickness of 5.0-25 μm thick, backed with carbon or Parylene, then a layer of highly conductive pressure sensitive adhesives. Metal foil tapes are commercially available from sources including Chomerics and Lebow Company.

Micro-finishing/Etching Step: Etched, micro-finished, or patterned surface shows an increase in adhesion to a laminating/coating layer that is needed to provide the structural support/integrity needed for the ultra-thin graphite layer. In one embodiment, the surface is patterned, mirofinished, or etched using techniques known in the art, including dry vacuum/plasma-assisted processes including ion etching, plasma etching, reactive ion etching or chemical etching, creating cracks, gaps, or pits on the graphene surface.

In one embodiment, etching is done via a physical process such as ion etching. In a second embodiment, the etching is via a chemical reaction such as plasma etching or oxidation. In a third embodiment, a combination of both physical and chemical effects such as reactive ion etching is used to microfinish the surface of the graphene. In one embodiment, the dry etching is done using a gas species such as oxygen, argon and a fluorine gas (such as Freon, SF₆ and CF₄). In one embodiment, the oxidative etching is done using an oxygen radical, so that carbon can be oxidized (burnt out) and converts to carbon dioxide, creating patterns on the graphene films. In one embodiment of oxidative etching, an oxygen molecule is irradiated with an ultraviolet ray to generate an oxygen radical for use in etching the surface of the graphene layer. In yet another embodiment, the graphene layer is etched by oxidizing at a temperature of 500 to 800° C., wherein it is noted that the density of the pits and the pit diameter on the graphene surface increases with the oxidation temperature.

Providing Structural Integrity to Graphene Layer(s): As the heat sink of the invention is fabricated from graphene layers of atomic layer thick, i.e., nanometer scale, the ultra-thin graphite layer is provided with structural integrity/support in the form of a coating layer (on one or both sides of the graphite layer), or laminated with a support layer (on one or both sides if needed). In one embodiment as illustrated in FIG. 2A, the ultra-thin graphite layer is coated on both sides or surfaces. In a second embodiment as illustrated in FIG. 2C, the graphite layer is only partially coated at the top or tip of the fin. In a third embodiment (not shown), only the bottom of the graphite layer is coated for structural support for a fin in a heat sink. In a fourth embodiment as in FIG. 2B, the graphite layer is coated with the same coating as the mounting frame.

In one embodiment and prior to coating, holes or vias with sizes between 0.1 to 5 mm in diameter and spacing between 2 to 25 mm apart are drilled through the ultra-thin graphite layer using methods known in the art including Electro Discharge Machining (EDM), Electro Discharge Grinding (EDG), laser, and plasma. In another embodiment, slits are fabricated in the ultra-thin graphite strip prior to treatments.

In one embodiment, the ultra-thin graphite strip having at least one graphene layer is coated or treated with a resin, a metal, a ceramic, or mixtures thereof Examples include parylene; silicon nitride, silicon oxide; nano particles of aluminum oxide, silicium oxide, zirconium oxide, titanium oxide, antimony oxide, zinc oxide, tin oxide, indium oxide, and cerium oxide, metal (e.g. aluminum or tungsten); cynoacrylate; a carbon film; a self-assembled monolayered material; perfluoropolyether; hexamethyldisilazane; perfluorodecanoic carboxylic acid; silicon dioxide; silicate glass; acrylic; epoxy; silicone; urethane; phenolic-based resin systems; or combinations thereof The coating provides moisture resistance, structural integrity, and handling strength, i.e. stiffness for the graphite layer, as well as “fixing” the morphology of the graphite layer.

The amount of coating used as well as the coating thickness should be sufficient so that the final ultra-thin graphite layer has sufficient structural integrity to be used as a heat sink, while the anisotropic thermal conductivity of the graphite is not adversely impacted. In one embodiment, the coating has a thickness between 50 nanometers and 1000 nanometers. In a second embodiment, the coating has a thickness of less than 500 nm. In a third embodiment, a sufficient amount of coating is applied so that the surface layer is sufficiently crack free, meaning that no cracks can be observed by optical microscopy or SEM with 10 k magnification. Cracks also include holes, perforations, pores, or lines.

The coating layer can be applied using processes known in the art, with the type of coating material used sometimes dictating the method of application. Examples of coating methods include but not limited to expanding thermal plasma (ETP), ion plating, plasma enhanced chemical vapor deposition (PECVD), metal organic chemical vapor deposition (MOCVD) (also called Organometallic Chemical Vapor Deposition (OMCVD)), metal organic vapor phase epitaxy (MOVPE), physical vapor deposition processes such as sputtering, reactive electron beam (e-beam) deposition, plasma spray, manual brushing, dipping, spraying, and flow coating.

For small/low volume heat sink applications, brushing can be used as this method is excellent for small volumes, but it can result in an inconsistency in coating thickness and that coating materials are generally “air dryable” solvent-based or moisture curable. Spraying can also be used, which can be done via a hand-held spray gun in a spray booth or an automated application system, with possible variations in the coating thickness uniformity and surface coverage. In another embodiment, flow coating is used for one side coating, wherein the graphite layer is passed over a “wave” of coating material at a specific angle, with the thickness of coating being controlled by the viscosity of the material and the speed with which it passes over the wave.

In one embodiment, Parylene C is used as the coating material for the ultra-thin heat sink, for a coating of a thin, inert and highly conformal film. The Parylene C can be applied on one or both sides of the graphite layer by a physical coating method such as brushing, dipping, or spraying. In a second embodiment, both sides of the ultra-thin heat sink are coated with Parylene C using a chemical vapor deposition process.

In yet another embodiment, due to the nano-structured and ultra-thin nature of the graphite layer, a flame spraying or a plasma deposition technique is employed for a coating thickness of less than 500 nanometer. In one embodiment, the coating comprises a metal, and wherein the ultra-thin graphite layer is exposed to an evaporated metal in a plasma coating process. In yet another embodiment, a layer of aluminum oxide is used as a coating layer, wherein aluminum metal is evaporated in an inductively coupled oxygen plasma, thus forming a layer on the exposed graphene surface.

In one embodiment, the resin used for treating or coating the graphite layer can act as an adhesive to further laminate the resin-treated graphite layer with another layer, e.g., a metal foil or another ultra-thin graphite layer. In one embodiment, epoxy is used as a coating layer, which layer, upon curing, adhesively bond the graphite layer to another layer for structural support, e.g., a metal foil. In yet another embodiment, a material like a ceramet (ceramic/metal) precursor is used in a flame spraying (plasma spraying) to form a coating layer/a support layer on one or both sides of the ultra-thin graphite layer, forming ultra-thin reinforced graphite strip, which can be further processed to form an ultra-thin fin or ultra-thin heat sink.

The ultra-thin fin/coated graphite layer in one embodiment can be subsequently brazed to other materials or parts, i.e., mounting frame, water-cooled system, etc., using brazing materials which by themselves may not wet the graphite layer.

Cutting/Forming Fins Having Desired Shapes: In one embodiment, the ultra-thin reinforced graphite strip is cut into a desired size by any of EDM, EDG, laser, plasma, or other methods known in the art. In one embodiment, after cutting, the strip can be formed or bent into desired shapes depending on the final thermal management application. In one embodiment, the strip is rolled into a tube, forming “pin fins.”

In one embodiment, the cutting/forming step is carried out after the graphite layer is reinforced with a laminate or a coating layer. In a second embodiment, the cutting/forming step is carried out prior to the laminating/coating process.

In yet another embodiment, louvers, slits or vias are formed or perforated in the graphite layer by any of EDM, EDG, laser, plasma, or other methods known in the art. In one embodiment, vias are formed in the graphite layer so that a diffusion bond can be formed via the plurality of via with a resin coating on both sides of the graphite layer. The vias may be anywhere from 1-5 mm in diameter and placed between 3-25 mm apart to optimize thermal and mechanical performance.

In a further embodiment, the graphite layer is specifically designed with a number of holes or vias to form a weak mechanical structure, with the filled or coated vias acting to support the structure while minimizing the stress that can be transmitted across the heat sink or thermal spreader. By adjusting the number and location of vias, the thermal conductivity through the TPG and the mechanical integrity of the TPG can be optimized for a particular application, as coating materials (e.g., parylene, metal, etc.) flow into and diffuse across the holes, this creates mechanical vias that cross-link the opposing faces together for improved section modulus. In another embodiment, engineered size and spacing of the vias help mitigate the low z-direction conductivity of TPG, providing enhanced through-the-thickness conductivity in the final product.

In yet another embodiment, the surface of the high thermal conductivity graphite layer is textured or roughened so that the layer can effectively bond and/or adhere to brazing materials, encapsulants or laminating materials.

Assembling the Ultra-Thin Heat Sink: The ultra-thin graphite layer in the form of a fin 14 is assembled for intimate contact with a mounting frame or base plate for heat to be effectively transferred through the fin 14, in the a-b direction (the height or length of the fin depending on the configuration). In one embodiment, the mounting frame (or base plate) comprises a plastic material to eliminate all machining and drilling. In a second embodiment, the plastic is molded of metal filled material for EMI shielding, or of a highly heat resistant so that the heat sink can be soldered to the base plate in assembly. In another embodiment, the mounting frame is stamped and formed of metal, which would not only eliminate machining and drilling, but would also aid in heat dissipation.

The ultra-thin heat sink can be affixed to the mounting frame by known methods, including but not limited to using adhesives, soldering, crimping, swaging, staking, brazing, bonding, welding and spot welding. In one embodiment as illustrated in FIGS. 3A and 3B, the attachment is via a crimping process. In a second embodiment, an adhesive is added to the slot prior to crimping to further engage the fin 14.

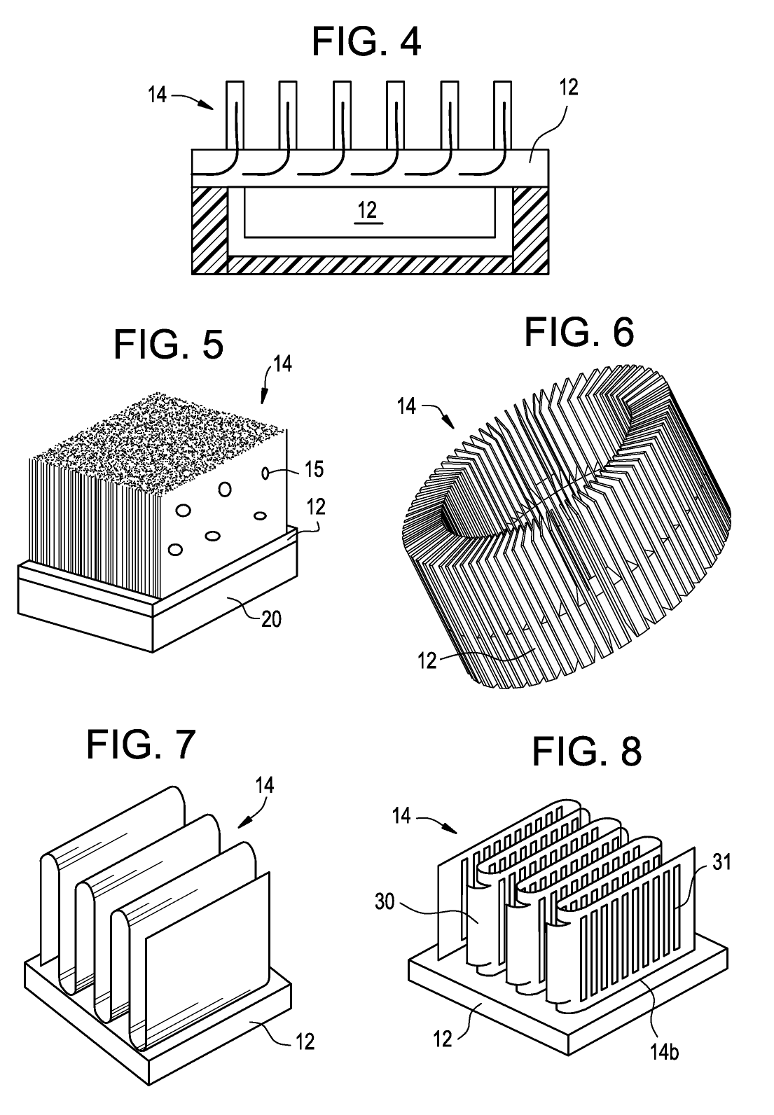

Since partially deform TPG still conducts heat with excellent thermal conductivity, in the embodiment as illustrated in FIG. 4, the coated/reinforced graphite fin 14 is bent such that a portion of the fin is oriented horizontally into the base plate 12 and the remaining portion is oriented vertically. In one embodiment of the invention and given the layered structure of the ultra-thin graphite layer, the bend is gradual to prevent failure of layer-to-layer bonds and complete fracture of the layer. In one embodiment to prevent fracture of the layer during bending, some graphene layers may be removed from the bent region (on the concave side of the bend relative to the horizontal end and the vertical end) to will limit bunching of the graphene layers on the concave side of the bend and subsequent compressive delamination and fracture. In yet another embodiment, the bent region may contain an array of holes to prevent the graphene layers from bunching. The holes allow for the layers to slide and fill the missing material, thus preventing compressive delamination and fracture of the strip.

In one embodiment, an adhesive is used to affix the ultra-thin graphite heat sink to the mounting frame. Adhesives, as used here, refer to any organic or inorganic/organic composite system which can be used to bond the heat sink. In one embodiment, the adhesive is a filled system, e.g., metal loaded polymers including silver loaded adhesives, composites of boron nitride (“BN”), Al2O3, silica or mixtures of these in a polymeric matrix such as BN filled epoxies, etc., which maintains a high degree of structural integrity at the use temperature and with adequate thermal conductivity. In yet another embodiment, a double sided thermally adhesive tape is used to securely attach each fin of the heat sink to the mounting frame.

In one embodiment, a braze that will wet the ultra-thin graphite layer is used to affix the ultra-thin graphite heat sink to the mounting frame. Examples of active brazes include “Ti—Cu-Sil” (titanium, copper, silver), brazes based on titanium and titanium hydride in combination of silicon and indium; and low temperature braze materials. In one embodiment, the brazes are applied in hard vacuum environment, e.g. around 10E-6 Torr and lower, allowing the braze to wet the graphene layers in the process of bonding the fin to the mounting frame.

Embodiments of the Ultra-Thin Heat Sink: The ultra-thin graphite heat sink of the invention can be bent, folded into same, shaped, encapsulated or laminated as fins for use in various different thermal management applications, including but not limited to cooling systems, heat sinks, heat spreaders and thermally conductive components. The number of fins, their dimensions and spacing vary depending on cooling requirements of the application.

Due to its ultra-thin and lightweight properties, the heat sink can provide optimized, thus performing better than the prior art thick thermal management solutions to remove heat from heat generating devices or installations. Exemplary applications range from commercial applications such as fuel cells, nuclear reactor, automotive, lap top computers, laser diodes, evaporators, etc. to defense-related and spacecraft applications including spacecrafts, jet fighters, etc, taking many shapes and forms, including but not limited to the embodiments described herein.

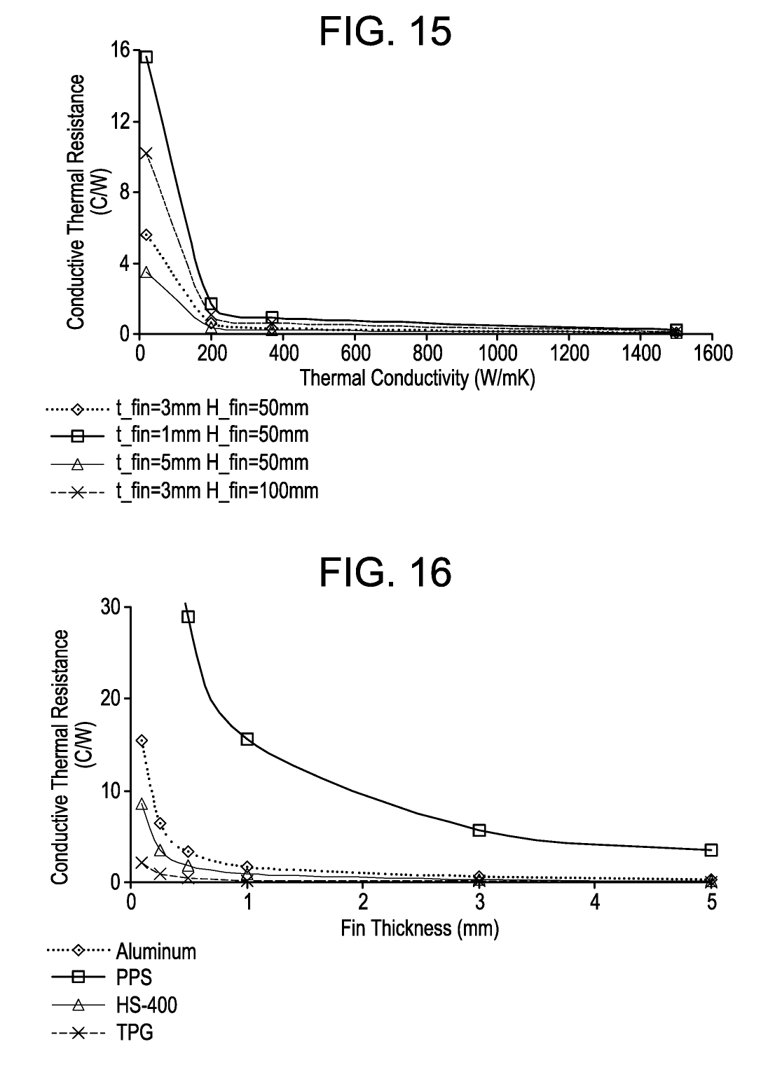

As illustrated in FIG. 15 from computer thermal models, the conductive thermal resistance varies little as a function of thermal conductivity in the range typically expected in thermal pyrolytic graphite, which is the material used in the heat sink of the invention. As illustrated in FIG. 16 for computer thermal models of heat sink assemblies employing different materials, the conductive thermal resistance for pyrolytic graphite is expected to be much less than that of heat sink assemblies employing materials of the prior art, i.e., aluminum, eGRAF® HS-400™ material, or polyphenylene sulfide (PPS). The heat sink of the present invention with its ultra-thin fins offers optimized conductive thermal resistance with its combination of maximum thermal conductivity and minimum thickness. It offers optimized thermal management in terms of maximum amount of heat that can be removed in terms of weight of the heat sink (i.e., the fins), or the total surface area available for heat removal/cooling.

Compared to the heat sink of the prior art, the ultra-thin heat sink is ultra light, i.e., TPG has a density of 2.18 to 2.24 g/cm³. This compares to a density of 8.9-g/cm³ for copper and 2.702-g/cm³ for aluminum. The use of graphite layers or cleavings from graphite sheet as the fins in the heat sink of the invention further allows the fin to be ultra-thin, for fin thickness ranging from a nanometer level, e.g, 5 nm or more, to less 50 mil (0.0254 mm), as compared to the prior art fins having thickness typically ranging from 0.25 mm to 0.75 mm. In one embodiment, the fin has a thickness ranging from 10 nm to 30 mil. In a second embodiment, from 50 nm to 20 mil. There is no upper limit to the thickness of the fins made from the ultra-thin graphite layer, however, it is desirable to have heat sinks that are as light as possible (and thus with fins as thin as possible down to several nanometer thick) for maximum heat removal capacity.

Due to the ultra-thin and ultra light property, the heat sink of the invention optimizes the amount of heat removal per surface area or weight of the heat sink (thermal conductivity of TPG of at least 1000 W/mK vs. 400 W/mK for copper, and 200 W/mK for aluminum). In one embodiment, the heat sink comprises a plurality of low profile heat sink having height of less than 10 mm and total weight of less than 1 gm, for use inside most telecommunications enclosures where space is limited. In one embodiment, the heat sink comprises between 20 to 100 fins each with a height of at least 10 mm and a width of at least 10 mm (total of at least 100 mm² area), and for a weight less than 5 gm.

In one embodiment, the ultra-thin heat sink comprises a plurality of fins having rectangular shape as shown in FIG. 5, with an aspect ratio (height to thickness) of the fins of higher than 100:1. The a-b axis of the fins 14 extends along and into the base plate 12. An electronic device such as a microprocessor 20 is thermally coupled to the base plate 12 using thermal interface materials. In another embodiment (not shown), an integral heat spreader can be applied between the electronic device 20 and the base plate 12.

In yet another embodiment as illustrated in FIG. 6, the heat sink comprises a plurality of radially distributed spaced fins 14, with a pair of fins being affixed to a vertical mounting frame 12. In one embodiment (not shown), the heat sink assembly further includes a fan to induce airflows for cooling the heat sink.

In one embodiment as illustrated in FIG. 7, after the graphite substrate is cut into the desired size, the substrate is folded into an accordion style such that there are alternating convoluted portions and planar portions. The folded fin 14 is placed on top of a base plate 12 such that convoluted portions on one side of fin 14 are abutted to the top surface of base plate 12, affixed to base plate 12 by brazing, soldering, or by adhesives.

In a second embodiment of a thermal management system as illustrated in FIG. 8, a folded fin 14 is form from a strip of ultra-thin graphite layer comprising graphene of carbon atom thickness. The folded fin 14 has a plurality of alternating planar portions and curved portions, forming a substantially convoluted accordion style fin with the curved portion of the fin is substantially perpendicular to and extend from the top surface of the base plate, and the straight edge 14b of the folded film 14 being affixed to the base plate 12. In one embodiment, louvers 30 are formed on each of the curved portion of the fin 14 to facilitate air passage and the convection of heat. In another embodiment also as illustrated, a plurality of slits 31 are incorporated in the fin 14. Although not shown in FIG. 8, a thermally conductive compound having selective phase change properties (i.e., liquefies during the operational temperature of the electronic component coupled to the heat sink) is provided on base plate 12 to help minimize air gaps. In one embodiment, the layer comprises a material that has both excellent thermal conductivity property as well as dielectric strength.

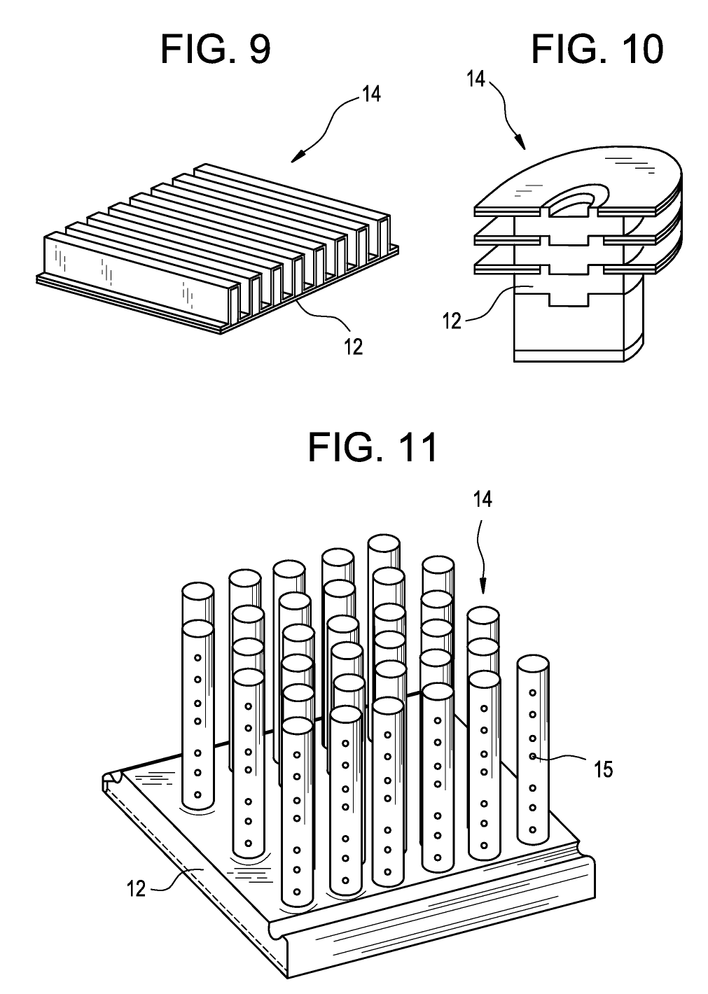

FIG. 9 illustrates another embodiment of a folded fin 14 assembly formed to have a generally serpentine configuration, and provided with a plurality of downwardly facing bends oriented to mate with the base plate 12.

In another embodiment as illustrated in FIG. 10, the ultra-thin heat fin is in the form of a radial finned heat sink, for use to cool a heat source such as an electronic component (like a chip assembly) such as those that are attached to printed circuit boards by ball grid arrays, wherein multiple parallel radial fins 14 supported by the base plate 12 are used. The base plate or mounting frame 12 may comprise graphite, metal, or a high temperature thermoplastic. Each fin member 14 has the graphene layers allied primarily with the plane of the fin 14 so that each fin 14 has the maximum thermal conductivity as expected of the ab direction of graphite.

In one embodiment as illustrated in FIG. 11, the ultra-thin strips are cut and formed into a plurality of “pin” fins 14. In one embodiment, the pins are also perforated or provided with a plurality of vias or holes to help mitigate the low z-direction conductivity of TPG, thus providing enhanced through-the-thickness conductivity in the final product. The dimensions of the pin fins (height and diameter of the pin) as well as the perforated holes can be design to optimize to optimize the airflow through the pins as well as the heat removal rate.

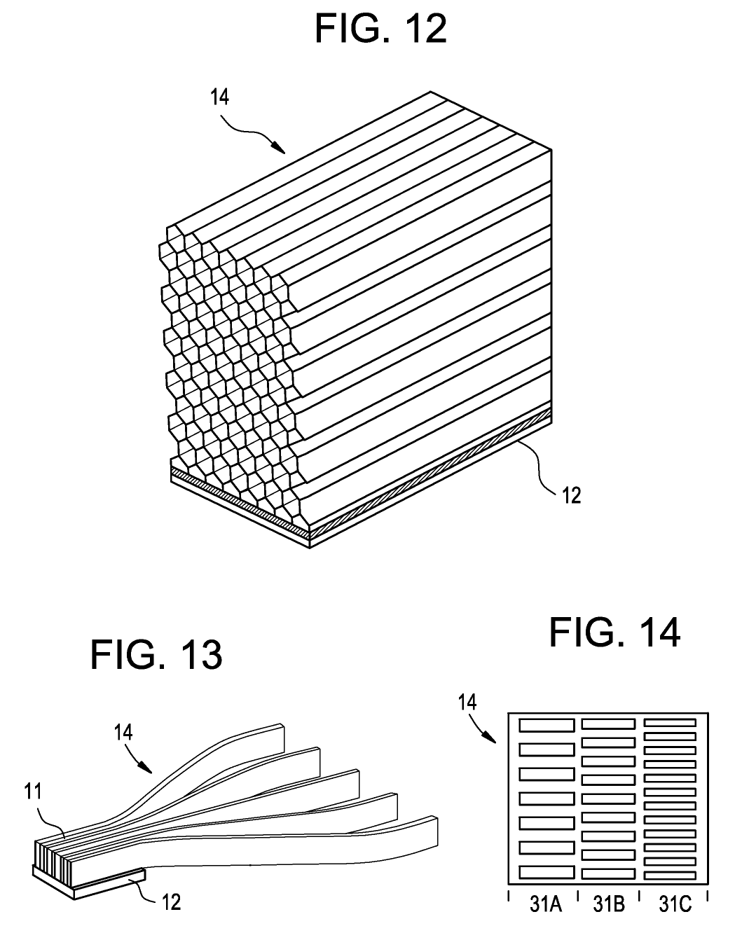

In one embodiment as illustrated in FIG. 12, the ultra-thin heat sink can be shaped to form fins 14 having an integral honeycomb-like cellular geometry, with each fin having a hexagonal or other open cellular structure. The honeycomb structure provides a maximized surface area for convective or other dissipation of heat transferred through the base portion. The structure further allows the network to exhibit degree flexibility or “spring” which allows the honeycomb to bend or otherwise conform to the base to accommodate curvatures and other deviations in planarity in the electronic package or other surface to which the base plate 12 is attached. The corrugated strips are bonded or otherwise joined, such as with an adhesive or solder, or by laser or spot welding, along the lengthwise extent of a corresponding trough of an adjacent strip in the stack and the base plate 12.

In yet embodiment as illustrated in FIG. 13, the ultra-thin heat sink is in the form of an expanded bundle, for the fins 14 being bundled in one end and attached to one another via bond line or adhesive material 11, with the other end of the fins 14 being spaced apart from adjacent fins, forming a splayed pattern. In another embodiment (not shown), the ultra-thin heat sink is in the form of a single concentric ring, or a plurality of concentric rings, squares, basically any geometry of different sizes, shapes, spacing, etc., designed to optimize the transport of heat from the electronic device to the ambient air.

It should be further noted that in all embodiments, the fin 14 can be optionally provided with a plurality of vias, slits or slots, to further facility the heat convection and air flow. The size of the vias and/or slits, their spacing can be varied according to the final application. In one embodiment as illustrated in FIG. 14, the fin 14 of the heat sink is provided with a different number of slits and with the number of slits increasing in successive stages. With the different stages in the fin 14, airflow channels can be customized depending on required thermal conduction of heat away from the electronic module as balanced against convective heat transfer from airflow channel walls.

Also, for all embodiments, pressure clips or brackets (not shown) can be optionally used to provide compressive force downward, further holding the folded fin 14 firmly seated in place/affixed to the base plate 12. In one embodiment of a radial finned or a honeycomb-style heat sink, a wire mesh, or net in the form of a perforated sheet is placed on top of the fins or honeycomb for holding the heat sink firmly seated in place.

### EXAMPLES

Examples are provided herein to illustrate the invention but are not intended to limit the scope of the invention.

### Example 1

A thermal pyrolytic graphite (TPG) sheet commercially available from General Electric Company is secured against a fat surface. A metal foil backed with a highly conductive adhesive tape, die cut to slightly overlap the TPG sheet, is pressed against the TPG Sheet. Metal foil tapes are commercially available from sources including Chomerics as CHO-FOIL® or CHO-FOIL® EMI shielding tapes. The metal foil sheet is peeled off, inducing the cleaving of the top graphene layer(s) from the pyrolytic graphite surface, and for the cleaving to be affixed to the adhesive backing of the metal foil tape. After the top cleaving is cleaved off, the process is repeated to obtain the next graphite cleaving.

### Example 2

The bare (not laminated) graphite layer surfaces of the metal-foil backed graphite strips in Example 1 are brushed with Parylene C using a small paint brush for thickness of 0.10, 0.25, 0.50, 0.75 and 1.00 mil (thousandth of an inch). The results show that as the thickness of Parylene increases, the mechanical robustness of the ultra-thin heat sink of the invention increases with the gain in robustness falling off at about 0.50 mil.

### Example 3

A two part, silver load, B-staged adhesive system is applied onto the bare graphite layer surface of the metal-foil backed strips obtained in Example. The resulting thermal conductivity of the heat sink is at least 75% of an uncoated TPG product.

While the invention has been described with reference to a preferred embodiment, those skilled in the art will understand that various changes may be made and equivalents may be substituted for elements thereof without departing from the scope of the invention. It is intended that the invention not be limited to the particular embodiment disclosed as the best mode for carrying out this invention, but that the invention will include all embodiments falling within the scope of the appended claims. All citations referred herein are expressly incorporated herein by reference.

We claim:

1. A thermal management assembly for dissipating thermal energy from a heat-generating device, the assembly comprising:
a base adapted to be thermally coupled to the heat generating device; and
at least a heat sink thermally coupled to the base, the heat sink comprises at least a graphite layer having a first surface, a second surface, and a thickness comprising at least a graphene layer, wherein the graphite layer is obtained by cleaving at least a graphene layer from a graphite sheet wherein the graphite layer exhibits a thermal conductivity which is anisotropic in nature and is greater than 500 W/m° C. in at least one plane, and
the heat sink further comprises a support layer which comprises at least one of a metal, a polymeric resin, a ceramic, and a mixture thereof, the support layer is disposed on at least one surface of the graphite layer by at least a process selected from the group consisting of: coating, brushing, spraying, spreading, dipping, laminating, and powder coating.

2. The thermal management assembly of claim 1, wherein prior to the support layer being disposed on the graphite layer, the graphite layer is treated by one of plasma etching, ion etching, chemical etching, and combinations thereof.

3. The thermal management assembly of claim 1, wherein the support layer comprises parylene.

4. The thermal management assembly of claim 3, wherein the support layer is formed by applying parylene onto at least a surface of the graphite layer, and wherein paralyene is applied onto the surface by one of brushing, dipping, spraying, and a chemical vapor deposition process.

5. The thermal management assembly of claim 1, wherein the support layer comprises a metal foil backed by a thermally conductive adhesive layer.

6. The thermal management assembly of claim 3, wherein the support layer is disposed on at least one surface of the graphite layer by
pressing a metal foil layer backed by the thermally conductive adhesive against a graphite sheet having a thickness of at least 0.1 mm and comprising a plurality of graphite layers, and
peeling off the metal foil layer for at least a graphite layer to be cleaved off the graphite sheet and affixed to the thermally conductive adhesive backing of the metal foil layer.

7. A heat dissipating fin for use in thermal management assemblies, the fin comprises at least a graphite layer having a first surface, a second surface, and a thickness comprising at least a graphene layer, wherein the graphite layer is obtained by cleaving at least a graphene layer from a graphite sheet exhibiting a thermal conductivity which is anisotropic in nature and is greater than 500 W/m° C. in at least one plane,
the graphite layer is reinforced by a support layer disposed on at least one surface of the graphite layer by at least a process selected from the group consisting of: coating, brushing, spraying, spreading, dipping, laminating, and powder coating.

8. The heat dissipating fin of claim 7, wherein the fin has a thickness ranging from 5 nanometer to 50 mil.

9. The heat dissipating fin of claim 8, wherein the fin has a thickness ranging from 10 nanometer to 30 mil.

10. The heat dissipating fin of claim 7, wherein the support layer comprises at least one of a resin, a metal, a ceramic, or mixtures thereof.

11. The heat dissipating fin of claim 10, wherein the support layer comprises at least one of: parylene; silicon nitride, silicon oxide; nano particles of aluminum oxide, silicium oxide, zirconium oxide, titanium oxide, antimony oxide, zinc oxide, tin oxide, indium oxide, cerium oxide, metal powder, cynoacrylate; a carbon film; perfluoropolyether; hexamethyldisilazane; perfluorodecanoic carboxylic acid; silicon dioxide; silicate glass; acrylic; epoxy; silicone; urethane; and a phenolic-based resin.

12. The heat dissipating fin of claim 7, wherein the graphite layer reinforced by a support layer disposed thereon is formed by pressing a metal foil layer backed by a thermally conductive adhesive against at least a surface of the graphite layer.

13. The heat dissipating fin of claim 7, wherein the graphite layer reinforced by a support layer disposed thereon is formed by pressing a metal foil layer having a thickness from 5.0 to 25 μm thick and backed by a layer of pressure sensitive adhesive against both surfaces of the graphite layer.

14. The heat dissipating fin of claim 7, wherein the graphite layer reinforced by a support layer disposed thereon is formed by coating at least a surface of the graphite layer by a plasma deposition process for the support layer to have a thickness of less than 500 nanometer.

15. The heat dissipating fin of claim 7, wherein the graphite layer reinforced by a support layer disposed thereon is fabricated into one of:
a radial or partially radial fin;
a folded fin having alternating and curved portions;
a corrugated fin having a plurality of cellular structures;
a plurality of fins in a splayed pattern with one bundled end and an expanded end with the fins at the expanded end being spaced apart from adjacent fins;
a rectangular fin;
a rectangular fin having a plurality of slits for defining at least an air passage through the heat sink;
a plurality of pin fins; and combinations thereof.

16. The heat dissipating fin of claim 7, wherein the graphite layer reinforced by a support layer disposed thereon is fabricated into a folded fin having alternating and curved portions, and wherein each curved portion has a plurality of vertical slits for defining at least an air passage through the heat sink.

17. A thermal management assembly comprising a plurality of the heat dissipating fins of claim 14.

18. A cooling system comprising:
an integrated circuit board;
a processor coupled to the integrated circuit board;
a heat sink thermally coupled to the processor, the heat sink comprising a base to transfer heat away from the processor, and a fin thermally coupled to the base, the fin comprising at least a graphite layer having first surface, a second surface, and a thickness comprising at least a graphene layer, the graphite layer is obtained by cleaving at least a layer from a graphite sheet exhibiting a thermal conductivity which is anisotropic in nature and is greater than 500 W/m° C. in at least one plane,
the heat sink further comprising a support layer comprising at least one of a metal, a polymeric resin, a ceramic, and a mixture thereof, the support layer is disposed on at least one surface of the graphite layer by at least a process selected from the group consisting of: coating, brushing, spraying, spreading, dipping, laminating, and powder coating.

19. A method for constructing a thermal management system, the method comprising:
constructing a fin by cleaving at least a graphite layer having a thickness of less than 1 mil from a sheet of graphite exhibiting a thermal conductivity which is anisotropic in nature and is greater than 500 W/m° C. in at least one plane, the graphite layer comprising at least a graphene layer;
coupling the fin to a base to form a heat sink; and
thermally coupling the heat sink to an integrated circuit such that the heat sink conducts thermal energy away from the integrated circuit during operation of the integrated circuit.

20. The method of claim 19, wherein the fin is coupled to the heat sink base by one of soldering, crimping, swaging, staking, brazing, bonding, welding, spot welding, using an adhesive.
